(19) United States
(12) Patent Application Publication
(10) Pub. No.: US 2025/0226275 A1
(43) Pub. Date: Jul. 10, 2025

(54) COMPONENT-EMBEDDED STRUCTURE FOR WARPAGE SUPPRESSION

(71) Applicant: INDUSTRIAL TECHNOLOGY RESEARCH INSTITUTE, Hsinchu (TW)

(72) Inventors: Yu-Wei HUANG, Chiayi City (TW); Chin-Hung WANG, Hsinchu City (TW)

(73) Assignee: INDUSTRIAL TECHNOLOGY RESEARCH INSTITUTE, Hsinchu (TW)

(21) Appl. No.: 18/405,601

(22) Filed: Jan. 5, 2024

(51) Int. Cl. H01L 23/24; H01C 7/00; H01F 27/02; H01G 2/10; H01L 23/31

(52) U.S. Cl. CPC H01L 23/24; H01C 7/00; H01F 27/022; H01G 2/10; H01L 23/3185

(57) ABSTRACT

A component-embedded structure for warpage suppression is provided. The component-embedded structure includes a first frame, a second frame, at least one component and an insulating material. The second frame is disposed within the first frame. The component is disposed within the second frame. The height of the first frame is higher than that of the second frame. The insulating material is filled between the first frame and the second frame, and between the second frame and the component.

### TECHNICAL FIELD

The disclosure relates to a component-embedded structure with stepped walls.

### BACKGROUND

“Component-embedded technology” is regarded as a key technology to successfully realize heterogeneous integration and promote the popularization of applications. It can improve electrical characteristics, reduce the length of the wires between components, and reduce the overall size of the final product, among other advantages. Therefore, it is regarded as a solution to many problems in today's electronics industry. Due to the chemical shrinkage caused by the embedded materials and the difference in thermal expansion coefficients between materials, however, warping of the wafer or panel during the production process can result in a poor production yield and increased costs. Insufficient thermal conductivity of the embedded material in the vertical direction is also a disadvantage.

### SUMMARY

In accordance with one embodiment of the disclosure, a component-embedded structure for warpage suppression is provided. The component-embedded structure includes a first frame, a second frame, at least one component and an insulating material. The second frame is disposed within the first frame. The component is disposed within the second frame. The height of the first frame is higher than that of the second frame. The insulating material is filled between the first frame and the second frame, and between the second frame and the component.

In accordance with another embodiment of the disclosure, a component-embedded structure for warpage suppression is provided. The component-embedded structure includes a first frame, a first ladder, at least one component and an insulating material. The first ladder is adjacent to the first frame. The height of the first frame is higher than that of the first ladder. The component is disposed within the first frame and the first ladder. The insulating material is filled between the first frame and the component.

In accordance with another embodiment of the disclosure, a component-embedded structure for warpage suppression is provided. The component-embedded structure includes a first frame, a first ladder and at least one component. The first ladder is adjacent to the first frame. The height of the first frame is higher than that of the first ladder. The first frame has corresponding grooves. The component is disposed within the first frame and the first ladder.

In accordance with another embodiment of the disclosure, a component-embedded structure for warpage suppression is provided. The component-embedded structure includes a first frame, a first ladder, at least one component and an insulating material. The first ladder is adjacent to the first frame. The height of the first frame is higher than that of the first ladder. The first ladder is located inside a part of the first frame. The component is disposed within the first frame and the first ladder. The insulating material is filled between the first frame and the component.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1A shows a cross-sectional view of a component-embedded structure for warpage suppression in accordance with one embodiment of the disclosure;

FIG. 1B shows a three-dimensional side view of a component-embedded structure for warpage suppression in accordance with one embodiment of the disclosure;

FIG. 2A shows a cross-sectional view of a component-embedded structure for warpage suppression in accordance with one embodiment of the disclosure;

FIG. 2B shows a three-dimensional side view of a component-embedded structure for warpage suppression in accordance with one embodiment of the disclosure;

FIG. 3 shows a three-dimensional side view of a component-embedded structure for warpage suppression in accordance with one embodiment of the disclosure;

FIGS. 4A-4G show cross-sectional views of some components in a component-embedded structure for warpage suppression in accordance with one embodiment of the disclosure;

FIG. 5 shows a cross-sectional view of some components in a component-embedded structure for warpage suppression in accordance with one embodiment of the disclosure;

FIG. 6A shows a top view of a component-embedded structure for warpage suppression in accordance with one embodiment of the disclosure;

FIG. 6B shows a cross-sectional view obtained along a cross-sectional line A-A′ in FIG. 6A in accordance with one embodiment of the disclosure;

FIG. 7 shows a cross-sectional view of a component-embedded structure for warpage suppression in accordance with one embodiment of the disclosure;

FIG. 8 shows a cross-sectional view of a component-embedded structure for warpage suppression in accordance with one embodiment of the disclosure;

FIG. 9 shows a cross-sectional view of a component-embedded structure group in accordance with one embodiment of the disclosure; and

FIG. 10 shows a comparison of warpage variation of wafers containing various component-embedded structures in accordance with one embodiment of the disclosure.

### DETAILED DESCRIPTION

Various embodiments or examples are provided in the following description to implement different features of the disclosure. The elements and arrangement described in the following specific examples are merely provided for introducing the disclosure and serve as examples without limiting the scope of the disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the components may be used or operated in different directions. When the component is turned to different directions (such as rotated 45 degrees or other directions), the spatially related adjectives used in it will also be interpreted according to the turned position. In some embodiments of the disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the disclosure is an approximate value. Namely, the meaning of “about”, “around” and “substantially” may be implied if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the disclosure and the background or the context of the disclosure, and should not be interpreted in an idealized or overly formal manner unless so defined.

The disclosure is to improve the warpage deformation of the heterogeneous integrated structure and promote heat dissipation in the vertical direction. The disclosure provides a component-embedded structure that utilizes stepped metal walls arranged around the component to achieve the effects of suppressing warpage deformation of the heterogeneous integrated structure and improving vertical heat dissipation.

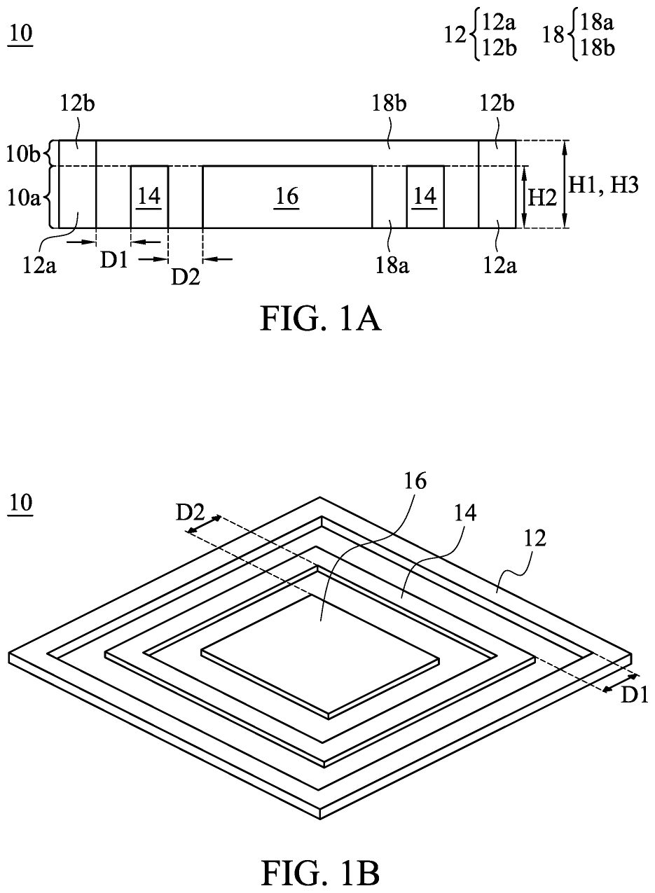

Referring to FIGS. 1A and 1B, in accordance with one embodiment of the disclosure, a component-embedded structure 10 for warpage suppression is provided. FIG. 1A shows a cross-sectional view of the component-embedded structure 10 for warpage suppression. FIG. 1B shows a three-dimensional side view of the component-embedded structure 10 for warpage suppression.

As shown in FIGS. 1A and 1B, the component-embedded structure 10 for warpage suppression includes a first frame 12, a second frame 14, a component 16 and an insulating material 18. The second frame 14 is disposed within the first frame 12. The component 16 is disposed within the second frame 14. The height H1 of the first frame 12 is higher than the height H2 of the second frame 14. The insulating material 18 is filled between the first frame 12 and the second frame 14, and between the second frame 14 and the component 16.

In one embodiment, there is a space D1 between the first frame 12 and the second frame 14. In one embodiment, the space D1 between the first frame 12 and the second frame 14 is between 0 and 1 mm. In one embodiment, the insulating material 18 covers the second frame 14 and the component 16. The height H3 of the insulating material 18 is equal to the height H1 of the first frame 12. In one embodiment, there is a space D2 between the second frame 14 and the component 16. In one embodiment, the space D2 between the second frame 14 and the component 16 is between 0.1 mm and 5 mm. In one embodiment, the first frame 12 and the second frame 14 are continuous walls and separated from each other (by the space D1). The first frame 12 and the second frame 14 form a continuous stepped wall located outside the component 16. For example, the second frame 14 surrounds the component 16, and the first frame 12 surrounds the second frame 14, as shown in FIG. 1B.

In one embodiment, the materials of the first frame 12 and the second frame 14 include metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

In one embodiment, the insulating material 18 includes molding materials, such as epoxy molding compound (EMC), liquid molding compound (LMC), sheet molding compound (SMC), anisotropic conductive film (ACF) or silicone, but the disclosure is not limited thereto, and other suitable molding materials are also applicable to the disclosure.

In addition, in accordance with FIG. 1A, the component-embedded structure 10 for warpage suppression is divided into a first region 10a and a second region 10b. The first portion 12a of the first frame 12, the second frame 14, and the first portion 18a of the insulating material 18 are disposed in the first region 10a of the component-embedded structure 10 (the component 16 is ignored here). The second portion 12b of the first frame 12 and the second portion 18b of the insulating material 18 are disposed in the second region 10b of the component-embedded structure 10.

At this time, if the volume ratio of the total volume of the first portion 12a of the first frame 12 and the second frame 14 in the first region 10a is defined as A, and the volume ratio of the volume of the second portion 12b of the first frame 12 in the second region 10b is defined as B, then A is greater than B. That is, the metal content (which is provided by the first portion 12a of the first frame 12 and the second frame 14) in the first region 10a is higher than the metal content (which is provided by the second portion 12b of the first frame 12) in the second region 10b. Furthermore, since the coefficient of thermal expansion (CTE) of metal materials is lower than that of insulating materials, and the Young's modulus of metal materials is higher than that of insulating materials, according to the following relevant warpage formula, it can be verified that the disclosure can reduce the warpage deformation of the component-embedded structure 10 by designing the metal content in the first region 10a to be higher than the metal content in the second region 10b (for example, the second frame 14 is disposed at the component side).

$$D = \frac{3 {L}^{2}}{4 ( {t}_{a} + {t}_{b} )} \frac{{( 1 + \frac{{t}_{a}}{{t}_{b}} )}^{2} ( {α}_{b} - {α}_{a} ) ( T - {T}_{0} )}{[ 3 {( 1 + \frac{{t}_{a}}{{t}_{b}} )}^{2} + ( 1 + \frac{{t}_{a} {E}_{a}}{{t}_{b} {E}_{b}} ) ( \frac{{t}_{a}^{2}}{{t}_{b}^{2}} + \frac{{t}_{b} {E}_{b}}{{t}_{a} {E}_{a}} ) ]}$$

In the above formula, D is the deformation amount, L is the length of the carrier, the subscripts a and b represent the physical properties of materials a and b respectively, t is the material thickness, a is the coefficient of thermal expansion (CTE) of the material, E is the Young's coefficient of the material, T is the ambient temperature. It can be seen from the formula that the deformation amount is proportional to the square of the length of the carrier, proportional to the difference in the coefficient of thermal expansion (CTE) and temperature difference, and related to the thickness ratio and Young's coefficient ratio between the two materials.

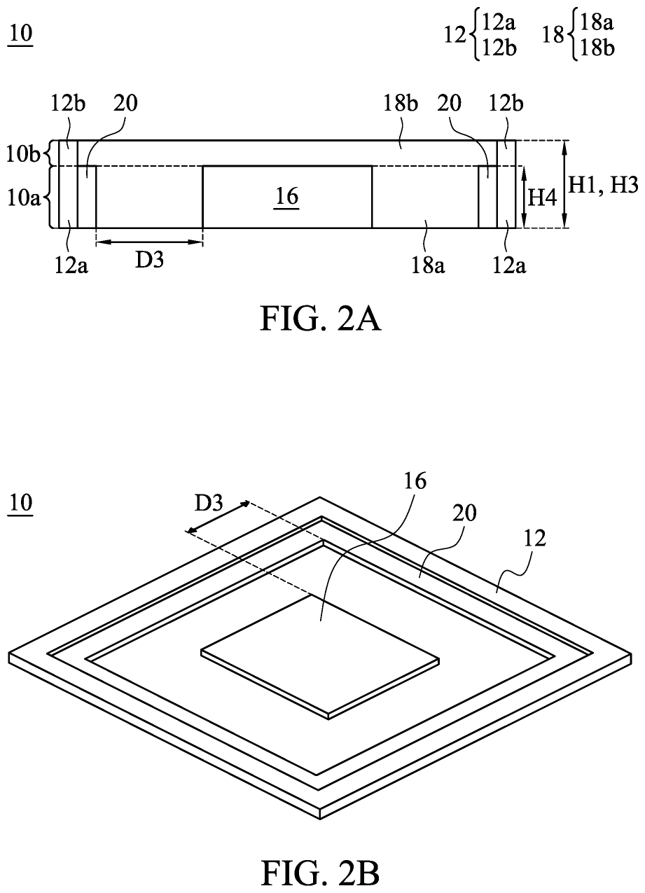

Referring to FIGS. 2A and 2B, in accordance with one embodiment of the disclosure, a component-embedded structure 10 for warpage suppression is provided. FIG. 2A shows a cross-sectional view of the component-embedded structure 10 for warpage suppression. FIG. 2B shows a three-dimensional side view of the component-embedded structure 10 for warpage suppression.

As shown in FIGS. 2A and 2B, the component-embedded structure 10 for warpage suppression includes a first frame 12, a first ladder 20, a component 16 and an insulating material 18. The first ladder 20 is adjacent to the first frame 12, for example, the first ladder 20 is in contact with the first frame 12. The height H1 of the first frame 12 is higher than the height H4 of the first ladder 20. The component 16 is disposed within the first frame 12 and the first ladder 20. The insulating material 18 is filled between the first frame 12 and the component 16.

In one embodiment, the insulating material 18 covers the first ladder 20 and the component 16. The height H3 of the insulating material 18 is equal to the height H1 of the first frame 12. In one embodiment, there is a space D3 between the first ladder 20 and the component 16. In one embodiment, the space D3 between the first ladder 20 and the component 16 is between 0.1 mm and 5 mm. In one embodiment, the first frame 12 and the first ladder 20 are continuous walls and connected to each other. The first frame 12 and the first ladder 20 form a continuous stepped wall located outside the component 16. For example, the first frame 12 and the first ladder 20 surround the component 16, as shown in FIG. 2B.

In one embodiment, the materials of the first frame 12 and the first ladder 20 include metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

In one embodiment, the insulating material 18 includes molding materials, such as epoxy molding compound (EMC), liquid molding compound (LMC), sheet molding compound (SMC), anisotropic conductive film (ACF) or silicone, but the disclosure is not limited thereto, and other suitable molding materials are also applicable to the disclosure.

In addition, in accordance with FIG. 2A, the component-embedded structure 10 for warpage suppression is divided into a first region 10a and a second region 10b. The first portion 12a of the first frame 12, the first ladder 20, and the first portion 18a of the insulating material 18 are disposed in the first region 10a of the component-embedded structure 10 (the component 16 is ignored here). The second portion 12b of the first frame 12 and the second portion 18b of the insulating material 18 are disposed in the second region 10b of the component-embedded structure 10.

At this time, if the volume ratio of the total volume of the first portion 12a of the first frame 12 and the first ladder 20 in the first region 10a is defined as A, and the volume ratio of the volume of the second portion 12b of the first frame 12 in the second region 10b is defined as B, then A is greater than B. That is, the metal content (which is provided by the first portion 12a of the first frame 12 and the first ladder 20) in the first region 10a is higher than the metal content (which is provided by the second portion 12b of the first frame 12) in the second region 10b. Furthermore, since the coefficient of thermal expansion (CTE) of metal materials is lower than that of insulating materials, and the Young's modulus of metal materials is higher than that of insulating materials, according to the above-mentioned relevant warpage formula, it can be verified that the disclosure can reduce the warpage deformation of the component-embedded structure 10 by designing the metal content in the first region 10a to be higher than the metal content in the second region 10b (for example, the first ladder 20 is disposed at the component side).

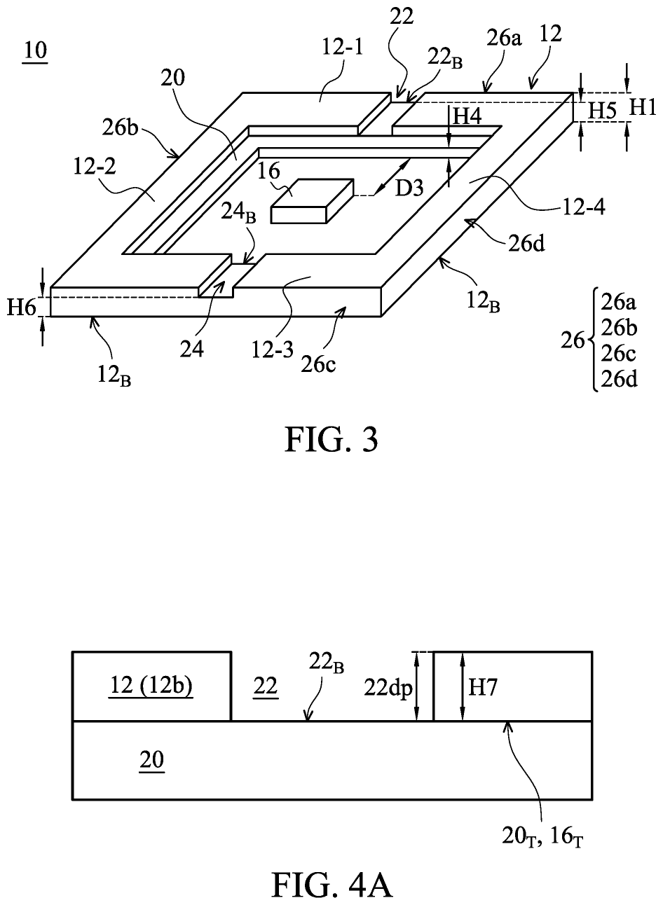

Referring to FIG. 3, in accordance with one embodiment of the disclosure, a component-embedded structure 10 for warpage suppression is provided. FIG. 3 shows a three-dimensional side view of the component-embedded structure 10 for warpage suppression.

As shown in FIG. 3, the component-embedded structure 10 for warpage suppression includes a first frame 12, a first ladder 20 and a component 16. The first ladder 20 is adjacent to the first frame 12, for example, the first ladder 20 is in contact with the first frame 12. The height H1 of the first frame 12 is higher than the height H4 of the first ladder 20. The first frame 12 has corresponding grooves (22 and 24). The component 16 is disposed within the first frame 12 and the first ladder 20.

In one embodiment, there is a space D3 between the first ladder 20 and the component 16. In one embodiment, the space D3 between the first ladder 20 and the component 16 is between 0.1 mm and 5 mm. In one embodiment, the first frame 12 and the first ladder 20 are continuous walls and connected to each other. The first frame 12 and the first ladder 20 form a continuous stepped wall 26 located outside the component 16. For example, the first frame 12 and the first ladder 20 surround the component 16, as shown in FIG. 3. According to FIG. 3, the continuous stepped wall 26 includes a first wall 26a, a second wall 26b, a third wall 26c, and a fourth wall 26d that are connected to each other. The first wall 26a is relative to the third wall 26c. The first wall 26a connects the second wall 26b and the fourth wall 26d. The third wall 26c connects the second wall 26b and the fourth wall 26d.

In one embodiment, the heights of the corresponding grooves (22 and 24) are equal. Here, the distance between the bottom of the groove and the bottom of the first frame is defined as the height of the groove. For example, the distance between the bottom 22_{B} of the groove 22 and the bottom 12_{B} of the first frame 12 is defined as the height H5 of the groove 22. The distance between the bottom 24_{B} of the groove 24 and the bottom 12_{B} of the first frame 12 is defined as the height H6 of the groove 24. In one embodiment, the height H5 of the groove 22 is equal to the height H6 of the groove 24. In one embodiment, the height H5 of the groove 22 is not equal to the height H6 of the groove 24.

In the disclosure, the groove can be disposed at any suitable position in the first frame 12. As shown in FIG. 3, the first frame 12 includes a first region 12-1, a second region 12-2, a third region 12-3 and a fourth region 12-4. The first region 12-1 is relative to the third region 12-3. The first region 12-1 connects the second region 12-2 and the fourth region 12-4. The third region 12-3 connects the second region 12-2 and the fourth region 12-4. In one embodiment, the groove 22 is disposed in the first region 12-1 of the first frame 12, and the groove 24 is disposed in the third region 12-3 of the first frame 12. That is, the grooves (22 and 24) are located in corresponding positions, as shown in FIG. 3.

In one embodiment, one of the grooves (22 and 24) is disposed in the second region 12-2 of the first frame 12, and the other of the grooves (22 and 24) is disposed in the fourth region 12-4 of the first frame 12. That is, the grooves (22 and 24) are located in corresponding positions (not shown). In one embodiment, one of the grooves (22 and 24) is disposed in the first region 12-1 of the first frame 12, and the other of the grooves (22 and 24) is disposed in the second region 12-2 of the first frame 12. That is, the grooves (22 and 24) are located in adjacent positions (not shown). In one embodiment, one of the grooves (22 and 24) is disposed in the first region 12-1 of the first frame 12, and the other of the grooves (22 and 24) is disposed in the fourth region 12-4 of the first frame 12. That is, the grooves (22 and 24) are located in adjacent positions (not shown). In one embodiment, one of the grooves (22 and 24) is disposed in the second region 12-2 of the first frame 12, and the other of the grooves (22 and 24) is disposed in the third region 12-3 of the first frame 12. That is, the grooves (22 and 24) are located in adjacent positions (not shown). In one embodiment, one of the grooves (22 and 24) is disposed in the third region 12-3 of the first frame 12, and the other of the grooves (22 and 24) is disposed in the fourth region 12-4 of the first frame 12. That is, the grooves (22 and 24) are located in adjacent positions (not shown). In the disclosure, the grooves serve as flow channels for insulating materials in the process.

In one embodiment, the materials of the first frame 12 and the first ladder 20 include metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

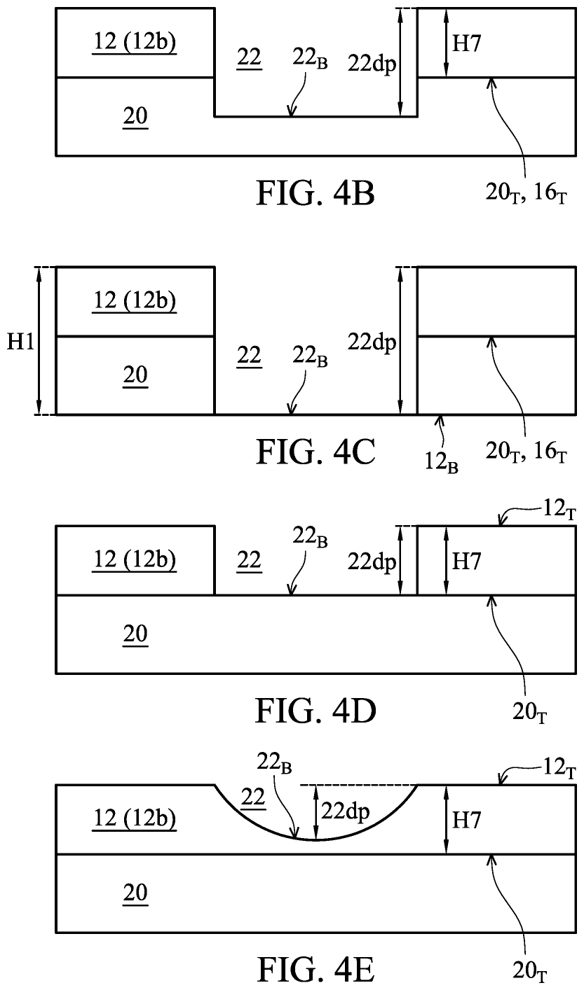

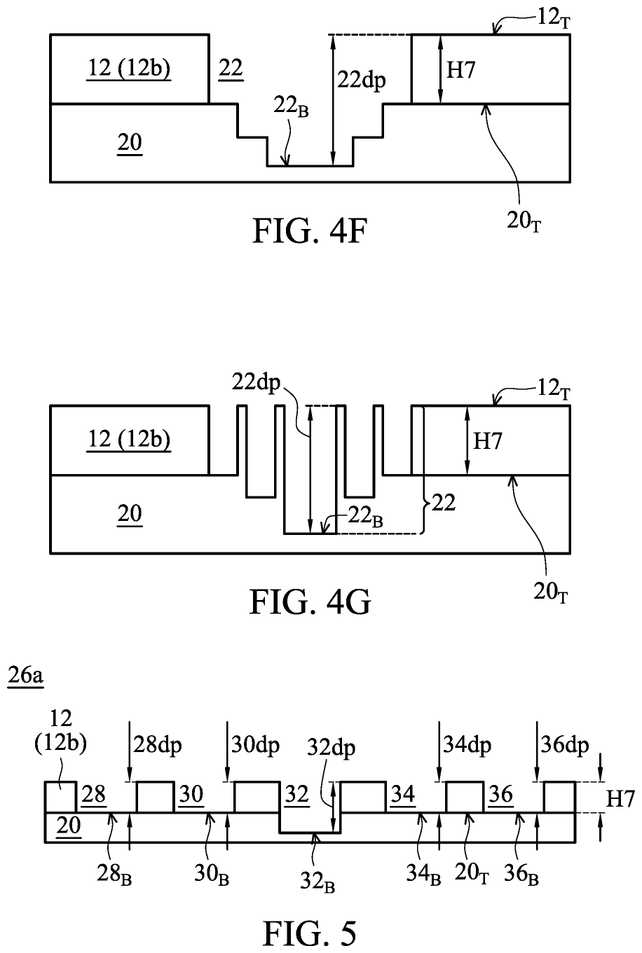

Referring to FIGS. 4A-4C, the depth variations of the grooves are further illustrated. Here, the groove 22 in FIG. 3 is taken as an example for illustration. FIGS. 4A-4C show cross-sectional views of some components in the component-embedded structure 10 for warpage suppression.

As shown in FIG. 4A, the groove 22 is disposed in the first frame 12. For example, the bottom 22_{B} of the groove 22 and the top 20_{T} of the first ladder 20 are located on the same plane, but the disclosure is not limited thereto. The bottom 22_{B} of the groove 22 may also be located in any position of the first frame 12 above the top 20_{T} of the first ladder 20 (not shown). At this time, the depth 22dp of the groove 22 is smaller than or equal to the height H7 of the first frame 12 (for example, the second portion 12b of the first frame 12, as shown in FIGS. 1A and 2A) located above the top 20_{T} of the first ladder 20. The top 20_{T} of the first ladder 20 is located on the same plane as the top 16_{T} of the component 16, but the disclosure is not limited thereto, in the disclosure, the top 20_{T} of the first ladder 20 and the top 16_{T} of the component 16 may also be located on different planes. In one embodiment, the groove 22 in the component-embedded structure 10 for warpage suppression is located above the component 16.

As shown in FIG. 4B, the groove 22 is disposed in the first frame 12 and extends downward to part of the first ladder 20, for example, the bottom 22_{B} of the groove 22 is located below the top 20_{T} of the first ladder 20. At this time, the depth 22dp of the groove 22 is greater than the height H7 of the first frame 12 (for example, the second portion 12b of the first frame 12, as shown in FIGS. 1A and 2A) located above the top 20_{T} of the first ladder 20. The top 20_{T} of the first ladder 20 is located on the same plane as the top 16_{T} of the component 16, but the disclosure is not limited thereto, in the disclosure, the top 20_{T} of the first ladder 20 and the top 16_{T} of the component 16 may also be located on different planes. In one embodiment, the groove 22 in the component-embedded structure 10 for warpage suppression extends downwardly beyond the component 16.

As shown in FIG. 4C, the groove 22 is disposed in the first frame 12 and extends downward through the first frame 12 and the first ladder 20, for example, the bottom 22_{B} of the groove 22 is located on the same plane as the bottom 12_{B} of the first frame 12. At this time, the depth 22dp of the groove 22 is approximately equal to the height H1 of the first frame 12. The top 20_{T} of the first ladder 20 is located on the same plane as the top 16_{T} of the component 16, but the disclosure is not limited thereto, in the disclosure, the top 20_{T} of the first ladder 20 and the top 16_{T} of the component 16 may also be located on different planes. In one embodiment, the groove 22 in the component-embedded structure 10 for warpage suppression extends downwardly beyond the component 16.

Referring to FIGS. 4D-4G, the shape variations of the grooves are further illustrated. Here, the groove 22 in FIG. 3 is taken as an example for illustration. FIGS. 4D-4G show cross-sectional views of some components in the component-embedded structure 10 for warpage suppression.

As shown in FIG. 4D, the groove 22 is disposed in the first frame 12 and has a downwardly concave square shape. For example, the bottom 22_{B} of the groove 22 extends downward from the top 12_{T} of the first frame 12 to the top 20_{T} of the first ladder 20 to form the groove 22 in a concave square shape. At this time, the depth 22dp of the concave-square groove 22 is equal to the height H7 of the first frame 12 (for example, the second portion 12b of the first frame 12, as shown in FIGS. 1A and 2A) located above the top 20_{T} of the first ladder 20. In one embodiment, the bottom 22_{B} of the groove 22 extends downward from the top 12_{T} of the first frame 12 to above the top 20_{T} of the first ladder 20 to form the groove 22 in a concave square shape. At this time, the depth 22dp of the concave-square groove 22 is smaller than the height H7 of the first frame 12 (for example, the second portion 12b of the first frame 12, as shown in FIGS. 1A and 2A) located above the top 20_{T} of the first ladder 20 (not shown). In one embodiment, the bottom 22_{B} of the groove 22 extends downward from the top 12_{T} of the first frame 12 to below the top 20_{T} of the first ladder 20 to form the groove 22 in a concave square shape. At this time, the depth 22dp of the concave-square groove 22 is greater than the height H7 of the first frame 12 (for example, the second portion 12b of the first frame 12, as shown in FIGS. 1A and 2A) located above the top 20_{T} of the first ladder 20 (not shown).

As shown in FIG. 4E, the groove 22 is disposed in the first frame 12 and has a downwardly concave arc shape. For example, the bottom 22_{B} of the groove 22 extends downward from the top 12_{T} of the first frame 12 to above the top 20_{T} of the first ladder 20 to form the groove 22 in a concave arc shape. At this time, the maximum depth 22dp of the concave-arc groove 22 is smaller than the height H7 of the first frame 12 (for example, the second portion 12b of the first frame 12, as shown in FIGS. 1A and 2A) located above the top 20_{T} of the first ladder 20. In one embodiment, the bottom 22_{B} of the groove 22 extends downward from the top 12_{T} of the first frame 12 to the top 20_{T} of the first ladder 20 to form the groove 22 in a concave arc shape. At this time, the maximum depth 22dp of the concave-arc groove 22 is equal to the height H7 of the first frame 12 (for example, the second portion 12b of the first frame 12, as shown in FIGS. 1A and 2A) located above the top 20_{T} of the first ladder 20 (not shown). In one embodiment, the bottom 22_{B} of the groove 22 extends downward from the top 12_{T} of the first frame 12 to below the top 20_{T} of the first ladder 20 to form the groove 22 in a concave arc shape. At this time, the maximum depth 22dp of the concave-arc groove 22 is greater than the height H7 of the first frame 12 (for example, the second portion 12b of the first frame 12, as shown in FIGS. 1A and 2A) located above the top 20_{T} of the first ladder 20 (not shown).

As shown in FIG. 4F, the groove 22 is disposed in the first frame 12 and extends downward to part of the first ladder 20. The shape of the groove 22 is a continuous symmetrical polygon that is concave downward (for example, the depth of the continuous symmetrical polygon decreases from the center to both sides). For example, the bottom 22_{B} of the groove 22 extends downward from the top 12_{T} of the first frame 12 to below the top 20_{T} of the first ladder 20 to form the groove 22 in the shape of a concave continuous symmetrical polygon. At this time, the maximum depth 22dp of the concave continuous symmetrical polygonal groove 22 is greater than the height H7 of the first frame 12 (for example, the second portion 12b of the first frame 12, as shown in FIGS. 1A and 2A) located above the top 20_{T} of the first ladder 20.

As shown in FIG. 4G, the groove 22 is disposed in the first frame 12 and extends downward to part of the first ladder 20. The shape of the groove 22 includes a plurality of discontinuous symmetrical rectangles that are concave downward (for example, the depths of the discontinuous symmetrical rectangles decrease from the center to both sides). For example, the bottom 22_{B} of the groove 22 extends downward from the top 12_{T} of the first frame 12 to below the top 20_{T} of the first ladder 20 to form a plurality of grooves 22 in the shape of concave discontinuous symmetrical rectangles. At this time, the maximum depth 22dp of the concave discontinuous symmetrical rectangular grooves 22 is greater than the height H7 of the first frame 12 (for example, the second portion 12b of the first frame 12, as shown in FIGS. 1A and 2A) located above the top 20_{T} of the first ladder 20.

Referring to FIG. 5, the variations in the number of grooves are further illustrated. Here, the first wall 26a (as shown in FIG. 3) is taken as an example for illustration. FIG. 5 shows a cross-sectional view of some components in the component-embedded structure 10 for warpage suppression.

As shown in FIG. 5, the first wall 26a composed of the first frame 12 and the first ladder 20 includes a plurality of grooves (for example, the first groove 28, the second groove 30, the third groove 32, the fourth groove 34 and the fifth groove 36) disposed therein. For example, the bottom 28B of the first groove 28 is on the same plane as the top 20_{T} of the first ladder 20. That is, the depth 28dp of the first groove 28 is equal to the height H7 of the first frame 12 (for example, the second portion 12b of the first frame 12, as shown in FIGS. 1A and 2A) located above the top 20_{T} of the first ladder 20. The shape of the first groove 28 is a downwardly concave square. The bottom 30B of the second groove 30 is on the same plane as the top 20_{T} of the first ladder 20. That is, the depth 30dp of the second groove 30 is equal to the height H7 of the first frame 12 (for example, the second portion 12b of the first frame 12, as shown in FIGS. 1A and 2A) located above the top 20_{T} of the first ladder 20. The shape of the second groove 30 is a downwardly concave square. The bottom 32B of the third groove 32 is on the same plane as the top 20_{T} of the first ladder 20. That is, the depth 32dp of the third groove 32 is equal to the height H7 of the first frame 12 (for example, the second portion 12b of the first frame 12, as shown in FIGS. 1A and 2A) located above the top 20_{T} of the first ladder 20. The shape of the third groove 32 is a downwardly concave square. The bottom 34B of the fourth groove 34 is on the same plane as the top 20_{T} of the first ladder 20. That is, the depth 34dp of the fourth groove 34 is equal to the height H7 of the first frame 12 (for example, the second portion 12b of the first frame 12, as shown in FIGS. 1A and 2A) located above the top 20_{T} of the first ladder 20. The shape of the fourth groove 34 is a downwardly concave square. The bottom 36B of the fifth groove 36 is on the same plane as the top 20_{T} of the first ladder 20. That is, the depth 36dp of the fifth groove 36 is equal to the height H7 of the first frame 12 (for example, the second portion 12b of the first frame 12, as shown in FIGS. 1A and 2A) located above the top 20_{T} of the first ladder 20. The shape of the fifth groove 36 is a downwardly concave square.

However, the depth and shape of each groove (for example, the first groove 28, the second groove 30, the third groove 32, the fourth groove 34 and the fifth groove 36) disposed in the first wall 26a are not limited to the above, and suitable groove patterns with other depths and shapes, as shown in FIGS. 4A-4G, are also applicable to the disclosure. In addition, the number of grooves disposed in a single wall (for example, the first wall 26a) is not limited to the above number (as shown in FIG. 5), and other suitable groove numbers are also applicable to the disclosure. Multiple grooves in a single wall are designed to be used with insulating materials with poor flows.

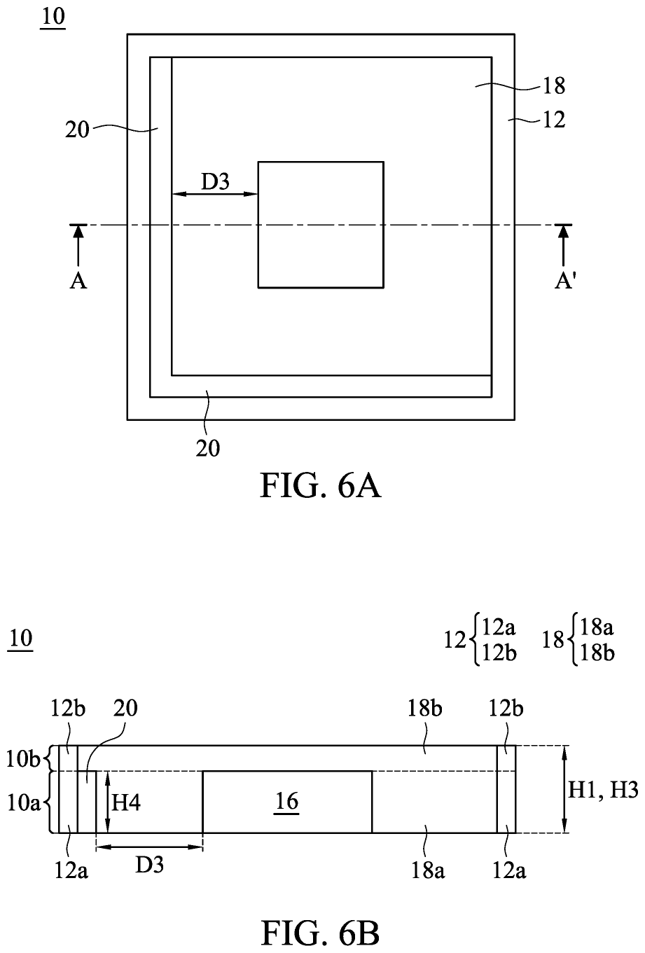

Referring to FIGS. 6A and 6B, in accordance with one embodiment of the disclosure, a component-embedded structure 10 for warpage suppression is provided. FIG. 6A shows a top view of the component-embedded structure 10 for warpage suppression. FIG. 6B shows a cross-sectional view obtained along a cross-sectional line A-A′ in FIG. 6A.

As shown in FIGS. 6A and 6B, the component-embedded structure 10 for warpage suppression includes a first frame 12, a first ladder 20, a component 16 and an insulating material 18. The first ladder 20 is adjacent to the first frame 12, for example, the first ladder 20 is in contact with the first frame 12. The height H1 of the first frame 12 is higher than the height H4 of the first ladder 20. The first ladder 20 is located inside a part of the first frame 12, that is, the first ladder 20 is not completely correspondingly disposed inside the first frame 12, so that a part of the inside of the first frame 12 is not in contact with the first ladder 20, as shown in FIG. 6A. The component 16 is disposed within the first frame 12 and the first ladder 20. The insulating material 18 is filled between the first frame 12 and the component 16.

In one embodiment, the insulating material 18 covers the first ladder 20 and the component 16. The height H3 of the insulating material 18 is equal to the height H1 of the first frame 12. In one embodiment, there is a space D3 between the first ladder 20 and the component 16. In one embodiment, the space D3 between the first ladder 20 and the component 16 is between 0.1 mm and 5 mm. In one embodiment, the first frame 12 and the first ladder 20 are continuous walls and connected to each other. The first frame 12 and the first ladder 20 form a continuous stepped wall located outside the component 16. For example, the first frame 12 and the first ladder 20 surround the component 16, as shown in FIG. 6A.

In one embodiment, the materials of the first frame 12 and the first ladder 20 include metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

In one embodiment, the insulating material 18 includes molding materials, such as epoxy molding compound (EMC), liquid molding compound (LMC), sheet molding compound (SMC), anisotropic conductive film (ACF) or silicone, but the disclosure is not limited thereto, and other suitable molding materials are also applicable to the disclosure.

In addition, in accordance with FIG. 6B, the component-embedded structure 10 for warpage suppression is divided into a first region 10a and a second region 10b. The first portion 12a of the first frame 12, the first ladder 20, and the first portion 18a of the insulating material 18 are disposed in the first region 10a of the component-embedded structure 10 (the component 16 is ignored here). The second portion 12b of the first frame 12 and the second portion 18b of the insulating material 18 are disposed in the second region 10b of the component-embedded structure 10.

At this time, if the volume ratio of the total volume of the first portion 12a of the first frame 12 and the first ladder 20 in the first region 10a is defined as A, and the volume ratio of the volume of the second portion 12b of the first frame 12 in the second region 10b is defined as B, then A is greater than B. That is, the metal content (which is provided by the first portion 12a of the first frame 12 and the first ladder 20) in the first region 10a is higher than the metal content (which is provided by the second portion 12b of the first frame 12) in the second region 10b. Furthermore, since the coefficient of thermal expansion (CTE) of metal materials is lower than that of insulating materials, and the Young's modulus of metal materials is higher than that of insulating materials, according to the above-mentioned relevant warpage formula, it can be verified that the disclosure can reduce the warpage deformation of the component-embedded structure 10 by designing the metal content in the first region 10a to be higher than the metal content in the second region 10b (for example, the first ladder 20 is disposed at the component side, and the first ladder 20 is located inside a part of the first frame 12, but is not completely correspondingly disposed inside the first frame 12).

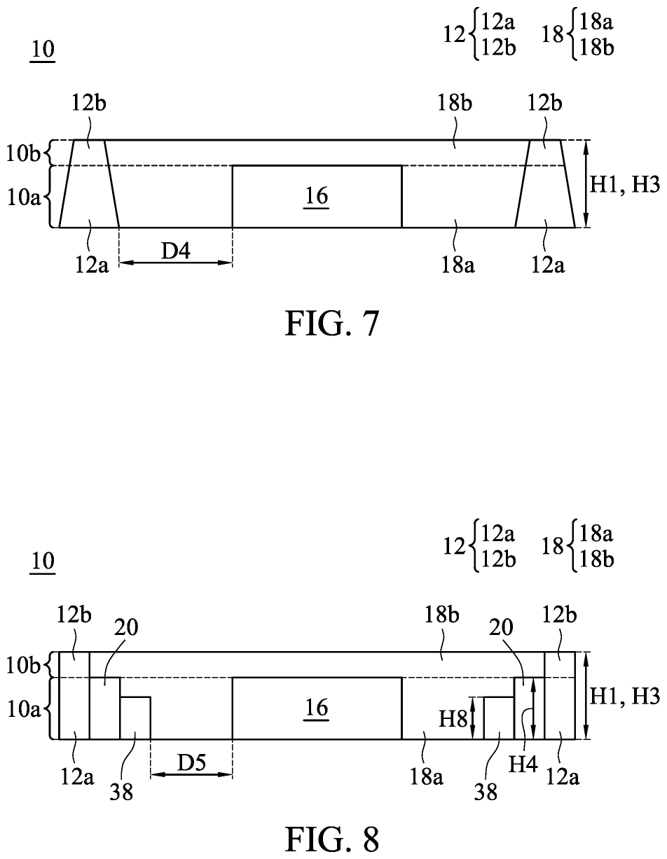

Referring to FIG. 7, in accordance with one embodiment of the disclosure, a component-embedded structure 10 for warpage suppression is provided. FIG. 7 shows a cross-sectional view of the component-embedded structure 10 for warpage suppression.

As shown in FIG. 7, the component-embedded structure 10 for warpage suppression includes a first frame 12, a component 16 and an insulating material 18. The component 16 is disposed within the first frame 12. The first frame 12 has a trapezoidal structure that is narrow at the top and wide at the bottom. The insulating material 18 is filled between the first frame 12 and the component 16.

In one embodiment, there is a space D4 between the first frame 12 and the component 16. In one embodiment, the space D4 between the first frame 12 and the component 16 is between 0.1 mm and 5 mm. In one embodiment, the insulating material 18 covers the component 16. The height H3 of the insulating material 18 is equal to the height H1 of the first frame 12. In one embodiment, the first frame 12 is a continuous wall. The first frame 12 forms a continuous ladder-like wall located outside the component 16. For example, the first frame 12 surrounds the component 16, as shown in FIG. 7.

In one embodiment, the materials of the first frame 12 includes metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

In one embodiment, the insulating material 18 includes molding materials, such as epoxy molding compound (EMC), liquid molding compound (LMC), sheet molding compound (SMC), anisotropic conductive film (ACF) or silicone, but the disclosure is not limited thereto, and other suitable molding materials are also applicable to the disclosure.

In addition, in accordance with FIG. 7, the component-embedded structure 10 for warpage suppression is divided into a first region 10a and a second region 10b. The first portion 12a of the first frame 12 and the first portion 18a of the insulating material 18 are disposed in the first region 10a of the component-embedded structure 10 (the component 16 is ignored here). The second portion 12b of the first frame 12 and the second portion 18b of the insulating material 18 are disposed in the second region 10b of the component-embedded structure 10.

At this time, if the volume ratio of the volume of the first portion 12a of the first frame 12 in the first region 10a is defined as A, and the volume ratio of the volume of the second portion 12b of the first frame 12 in the second region 10b is defined as B, then A is greater than B. That is, the metal content (which is provided by the first portion 12a of the first frame 12) in the first region 10a is higher than the metal content (which is provided by the second portion 12b of the first frame 12) in the second region 10b. Furthermore, since the coefficient of thermal expansion (CTE) of metal materials is lower than that of insulating materials, and the Young's modulus of metal materials is higher than that of insulating materials, according to the above-mentioned relevant warpage formula, it can be verified that the disclosure can reduce the warpage deformation of the component-embedded structure 10 by designing the metal content in the first region 10a to be higher than the metal content in the second region 10b (for example, the first frame 12 that is narrow at the top and wide at the bottom (for example, a trapezoidal structure) is disposed in the component-embedded structure).

Referring to FIG. 8, in accordance with one embodiment of the disclosure, a component-embedded structure 10 for warpage suppression is provided. FIG. 8 shows a cross-sectional view of the component-embedded structure 10 for warpage suppression.

As shown in FIG. 8, the component-embedded structure 10 for warpage suppression includes a first frame 12, a first ladder 20, a second ladder 38, a component 16 and an insulating material 18. The first ladder 20 is adjacent to the first frame 12, for example, the first ladder 20 is in contact with the first frame 12. The second ladder 38 is adjacent to the first ladder 20, for example, the second ladder 38 is in contact with the first ladder 20. The height H1 of the first frame 12 is higher than the height H4 of the first ladder 20. The height H4 of the first ladder 20 is higher than the height H8 of the second ladder 38. The component 16 is disposed within the first frame 12, the first ladder 20 and the second ladder 38. The insulating material 18 is filled between the first frame 12 and the component 16.

In one embodiment, the insulating material 18 covers the first ladder 20, the second ladder 38 and the component 16. The height H3 of the insulating material 18 is equal to the height H1 of the first frame 12. In one embodiment, there is a space D5 between the second ladder 38 and the component 16. In one embodiment, the space D5 between the second ladder 38 and the component 16 is between 0.1 mm and 5 mm. In one embodiment, the first frame 12, the first ladder 20 and the second ladder 38 are continuous walls and connected to each other. The first frame 12, the first ladder 20 and the second ladder 38 form a continuous stepped wall located outside the component 16. For example, the first frame 12, the first ladder 20 and the second ladder 38 surround the component 16, as shown in FIG. 8.

In one embodiment, the materials of the first frame 12, the first ladder 20 and the second ladder 38 include metal materials, such as tin, silver, copper, nickel, germanium, lead, antimony, bismuth, cadmium, gold, indium, aluminum, arsenic, iron, zinc, or alloys thereof, but the disclosure is not limited thereto, and other suitable metal materials are also applicable to the disclosure.

In one embodiment, the component 16 includes an active component, such as a transistor or a diode, but the disclosure is not limited thereto, and other suitable active components are also applicable to the disclosure. In one embodiment, component 16 includes a passive component, such as a resistor, a capacitor or an inductor, but the disclosure is not limited thereto, and other suitable passive components are also applicable to the disclosure.

In one embodiment, the insulating material 18 includes molding materials, such as epoxy molding compound (EMC), liquid molding compound (LMC), sheet molding compound (SMC), anisotropic conductive film (ACF) or silicone, but the disclosure is not limited thereto, and other suitable molding materials are also applicable to the disclosure.

In addition, in accordance with FIG. 8, the component-embedded structure 10 for warpage suppression is divided into a first region 10a and a second region 10b. The first portion 12a of the first frame 12, the first ladder 20, the second ladder 38 and the first portion 18a of the insulating material 18 are disposed in the first region 10a of the component-embedded structure 10 (the component 16 is ignored here). The second portion 12b of the first frame 12 and the second portion 18b of the insulating material 18 are disposed in the second region 10b of the component-embedded structure 10.

At this time, if the volume ratio of the total volume of the first portion 12a of the first frame 12, the first ladder 20 and the second ladder 38 in the first region 10a is defined as A, and the volume ratio of the volume of the second portion 12b of the first frame 12 in the second region 10b is defined as B, then A is greater than B. That is, the metal content (which is provided by the first portion 12a of the first frame 12, the first ladder 20 and the second ladder 38) in the first region 10a is higher than the metal content (which is provided by the second portion 12b of the first frame 12) in the second region 10b. Furthermore, since the coefficient of thermal expansion (CTE) of metal materials is lower than that of insulating materials, and the Young's modulus of metal materials is higher than that of insulating materials, according to the above-mentioned relevant warpage formula, it can be verified that the disclosure can reduce the warpage deformation of the component-embedded structure 10 by designing the metal content in the first region 10a to be higher than the metal content in the second region 10b (for example, a plurality of ladders are disposed at the component side, for example, the first ladder 20 and the second ladder 38 are disposed at the component side).

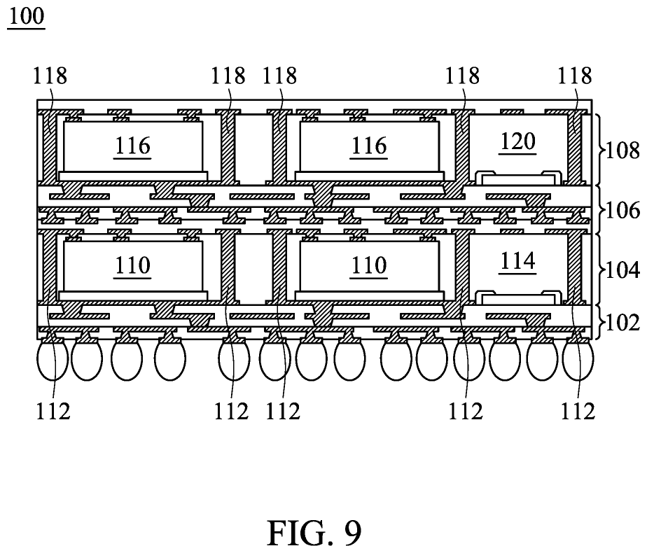

Referring to FIG. 9, in accordance with one embodiment of the disclosure, a component-embedded structure group 100 is provided. FIG. 9 shows a cross-sectional view of the component-embedded structure group 100.

As shown in FIG. 9, the component-embedded structure group 100 is a stacked component-embedded structure. The component-embedded structure group 100 includes a first redistribution layer 102, a first component-embedded structure 104, a second redistribution layer 106, and a second component-embedded structure 108. The first component-embedded structure 104 is disposed on the first redistribution layer 102. The second redistribution layer 106 is disposed on the first component-embedded structure 104. The second component-embedded structure 108 is disposed on the second redistribution layer 106.

In FIG. 9, the first component-embedded structure 104 includes a first component 110, a first metal wall 112 and a first insulating material 114. The first metal wall 112 surrounds the first component 110. The first insulating material 114 is filled between the first component 110 and the first metal wall 112. The profile of the first metal wall 112 in the first component-embedded structure 104 is similar to the continuous wall as shown in FIG. 1A, 2A, 3, 4A-4G, 5, 6B, 7 or 8. The second component-embedded structure 108 includes a second component 116, a second metal wall 118 and a second insulating material 120. The second metal wall 118 surrounds the second component 116. The second insulating material 120 is filled between the second component 116 and the second metal wall 118. The profile of the second metal wall 118 in the second component-embedded structure 108 is similar to the continuous wall as shown in FIG. 1A, 2A, 3, 4A-4G, 5, 6B, 7 or 8.

The component-embedded structure of the disclosure can effectively suppress the warpage phenomenon during the manufacturing process. For PoP stacked packaging that focuses on warpage issues, the component-embedded structure of the disclosure can reduce the warpage of the overall package. If the stacked component-embedded structure dissipates heat through the insulating material in the structure, the component may easily crack due to the slow heat-dissipation rate of the insulating material. In the disclosure, the heat generated by the component can be conducted to the metal walls on both sides through the conductive lines (for example, the redistribution layer) under the component-embedded structure, and then quickly conducted upward through the metal walls to the surface of the component-embedded structure group, and then the heat is dissipated by convection or radiation. The component-embedded structure of the disclosure can be applied to stacked structures (highly integrated packaging) to achieve good heat dissipation effect.

### Example

### Wafer Warpage Test

In this example, wafers containing three types of component-embedded structures (I, II and III) were used to conduct warpage variation tests. The component-embedded structure I is the component-embedded structure as shown in FIG. 1A (for example, the second frame 14 is disposed at the component side). The component-embedded structure II is the component-embedded structure as shown in FIG. 2A (for example, the first ladder 20 is disposed at the component side). The component-embedded structure III is a component-embedded structure without metal walls.

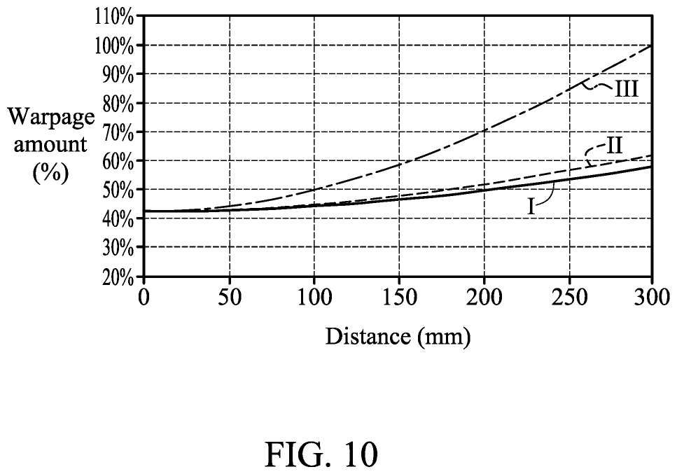

The results of the warpage tests are shown in FIG. 10. The abscissa in FIG. 10 is the distance from the center to the edge of the wafer, which is approximately 300 mm, and the ordinate is the wafer warpage amount (%). It can be seen from the test results in FIG. 10 that the amount of warpage of the wafer containing the component-embedded structure I (for example, the second frame 14 is disposed at the component side) is approximately 58% of that of the wafer containing the component-embedded structure III (without metal walls). The amount of warpage of the wafer containing the component-embedded structure II (for example, the first ladder 20 is disposed at the component side) is approximately 62% of that of the wafer containing the component-embedded structure III (without metal walls). It can be verified from this that the disclosure can indeed achieve the effect of suppressing wafer warpage by setting up a stepped wall structure, thereby improving the process yield and the feasibility of high-density and high-performance applications.

The disclosure aims to provide a special stepped wall structure to improve the warping deformation caused by the different amounts of thermal deformation between heterogeneous structures, and at the same time improve the vertical heat dissipation effect.

Although some embodiments of the disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the disclosure. Moreover, the scope of the application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the disclosure. Accordingly, the appended claims are intended to include within their scope such processes, machines, manufacture, compositions of matter, means, methods or steps. In addition, each claim constitutes an individual embodiment, and the claimed scope of the disclosure includes the combinations of the claims and embodiments. The scope of protection of disclosure is subject to the definition of the scope of the appended claims. Any embodiment or claim of the disclosure does not need to meet all the purposes, advantages, and features disclosed in the disclosure.

What is claimed is:

1. A component-embedded structure for warpage suppression, comprising:
a first frame;
a second frame disposed within the first frame;
at least one component disposed within the second frame, wherein the first frame has a greater height than that of the second frame; and
an insulating material filled between the first frame and the second frame, and between the second frame and the component.

2. The component-embedded structure for warpage suppression as claimed in claim 1, wherein there is a space between the first frame and the second frame.

3. The component-embedded structure for warpage suppression as claimed in claim 1, wherein the insulating material covers the second frame and the component, and the insulating material has a height equal to the height of the first frame.

4. The component-embedded structure for warpage suppression as claimed in claim 1, wherein there is a space between the second frame and the component.

5. A component-embedded structure for warpage suppression, comprising:
a first frame;
a first ladder adjacent to the first frame, wherein the first frame has a greater height than that of the first ladder;
at least one component disposed within the first frame and the first ladder; and
an insulating material filled between the first frame and the component.

6. The component-embedded structure for warpage suppression as claimed in claim 5, wherein the insulating material covers the first ladder and the component, and the insulating material has a height equal to the height of the first frame.

7. The component-embedded structure for warpage suppression as claimed in claim 5, wherein there is a space between the first ladder and the component.

8. A component-embedded structure for warpage suppression, comprising:
a first frame;
a first ladder adjacent to the first frame, wherein the first frame has a greater height than that of the first ladder, and the first frame has corresponding grooves; and
at least one component disposed within the first frame and the first ladder.

9. The component-embedded structure for warpage suppression as claimed in claim 8, wherein the corresponding grooves have the same height.

10. The component-embedded structure for warpage suppression as claimed in claim 9, wherein the grooves are located above the component.

11. The component-embedded structure for warpage suppression as claimed in claim 9, wherein the grooves extend downward beyond the component.

12. The component-embedded structure for warpage suppression as claimed in claim 9, wherein the grooves are concave arc or concave square.

13. A component-embedded structure for warpage suppression, comprising:
a first frame;
a first ladder adjacent to the first frame, wherein the first frame has a greater height than that of the first ladder, and the first ladder is located inside a part of the first frame;
at least one component disposed within the first frame and the first ladder; and
an insulating material filled between the first frame and the component.

14. The component-embedded structure for warpage suppression as claimed in claim 13, wherein the insulating material covers the first ladder and the component, and the insulating material has a height equal to the height of the first frame.

15. The component-embedded structure for warpage suppression as claimed in claim 13, wherein there is a space between the first ladder and the component.
